(19) United States
(12) Patent Application Publication
(10) Pub. No.: US 2009/0015447 A1
(43) Pub. Date: Jan. 15, 2009

(54) METHOD FOR PROCESSING DATA USING QUANTUM SYSTEM

(76) Inventor: Daniel KILBANK, Gaithersburg, MD (US)

Correspondence Address: GOTTLIEB RACKMAN & REISMAN PC, 270 MADISON AVENUE, 8TH FLOOR, NEW YORK, NY, 10016-0601, US

(21) Appl. No.: 12/048,425

(22) Filed: Mar. 14, 2008

Related U.S. Application Data
(60) Provisional application No. 60/895,250, filed on Mar. 16, 2007.

(51) Int. Cl. H03M 7/00

(52) U.S. Cl. 341/60

(57) ABSTRACT

A method and system for encoding or processing data is provided. Data is represented by a qubit. The qubit is generated by an emulator within an encoding system. The qubit is entangled with another qubit to create encoded data. The encoded data is useable for a non-quantum environment. The qubit and the another qubit are entangled by reconfiguring a quantum structure that is mapped onto the encoded data.

### BACKGROUND OF THE INVENTION

1. Field of the Invention

The present invention relates to encoding and representing information for data exchange, data storage, and the like, and, more particularly, systems and methods for mapping bits onto a representation that is compatible with existing software, computers, hardware and the like, and delivers the encoded bits using quantum representations.

2. Description of the Related Art

As networks, systems and other communication devices move towards digital, the demands being placed on these are increasing. Users and applications require increasing amounts of data and information in a real time manner. Some attempts to meet these demands include compressing data according to known compression algorithms. Data compression is well known and many standards exist that define processes for compressing data to be more suitable for transmitting as an analog signal over existing networks. One potential drawback of compression is the possibility of losing data, first when compressing the data from a certain size to a smaller size of data, and second, when decompressing the data back to its original size. The compression algorithm “loses” that data that it determines is not essential or needed to effectively display or transmit the information. In certain instances, this loss of data may be critical or over-reaching.

As additional demands are placed on the transmission and the storage of information and data, compression algorithms are becoming increasingly less efficient or practical in representing large data files, such as movies, transmitted over the network. Too much data is being lost or misrepresented to a user or other entity on the delivery side of a network, Further, as businesses become more reliant and familiar with electronic documents and other aspects of electronic storage, resources are being used to store data, documents, files and the like at additional costs and without any practical solution for storing increasingly large files or data in the future.

For example, a company may generate e-reports or newsletters to send to potential clients and customers. As the weeks, months and years go by, the storage of these newsletters may become a critical factor because of the size of the newsletters and how long the newsletters are retained. As the newsletters attempt to keep up with competitors and advancing technologies, the company may add digital photos, video files, charts, data and the like to the newsletters to provide more information to readers. The features require larger data files for each newsletter and additional storage space to retain newsletter records. Presently, the only alternative in transmitting and storing data is to buy ever increasing amounts of memory or buffer space, and to improve transmission network infrastructure to handle the larger files. These attempts mean additional costs to the company and additional equipment needs.

Another constraint on attempts to improve over existing data delivery and storage is the existing systems themselves. Cable, co-axial, wireless, fiber optic, and the like deliver data as binary bits with a value of either 0 or 1. Data is converted from images, audio, text, and so on into bits that are transmitted over networks and systems. This process may be known as binary encoding. Binary encoding is limited in how it can represent data and information. Alternatives to binary encoding, such as quantum computers, are cost prohibitive and would require much disruption in implementation with known and classical systems. Thus, any solution to the above would improve on existing binary encoding techniques and systems while being compatible with those systems do as to be cost effective and non-disruptive.

### SUMMARY OF THE INVENTION

According to the disclosed embodiments, a method for processing data is disclosed. The method includes generating a qubit to represent data. The method also includes entangling the qubit with another qubit by reconfiguring a quantum structure with the qubit or the another qubit. The method also includes mapping the quantum structure into encoded data. The encoded data is useable for a non-quantum environment.

Further according to the disclosed embodiments, a method for encoding data is disclosed. The method includes creating a quantum structure for properties of an electron. The method also includes encoding the quantum structure into a qubit. The method also includes entangling the qubit into encoded data. The method also includes adding an index to the encoded data. The index corresponds to a probability of a state for the qubit.

Further according to the disclosed embodiments, an encoding system is disclosed. The encoding system includes an emulator to generate a qubit having a quantum structure having properties for an electron. The encoding system also includes another qubit to entangle with the qubit to generate encoded data representing data. The encoding system also includes an input to receive the data. A probability is determined for a state of the qubit and the another qubit, and an index is added to the encoded data correlating to the probability.

The disclosed embodiments also may be used in conjunction with consumer electronics and hardware, such as a personal computer, a desktop computer, a notebook/laptop computer, a server, a mainframe, any consumer or business application/appliances such as a toaster, refrigerator, coffee maker, stove, freezer, trash compactor, wine cooler, furnace, water heater, air conditioner/temperature control system, pool, jacuzzi/hot tub, septic/sewer system, electric/oil/gas system, water system, HVAC/water/steam/hydraulic system, street traffic system, reference/guidance/air traffic control/radar/water or road navigation/feet monitoring/GPS system/lighting system/security system, sprinkler/fire suppression system, any video conferencing, a tape player/walkman, a digital disc player/minidisk/I-pod/small hard drive disc player, a flash memory player, a television, a stereo, a store image camera, a camcorder, a motion picture camera, a projector, a slide projector, an electronic white board, and the like.

### BRIEF DESCRIPTION OF THE DRAWINGS

For proper understanding of the invention, reference should be made to the accompanying drawings, wherein:

FIG. 1 illustrates a block diagram of an encoding system according to the disclosed embodiments.

FIG. 2 illustrates a flowchart for processing data according to the disclosed embodiments.

FIG. 3 illustrates a waveform of proloilities of a quantum state according to the disclosed embodiments.

### DETAILED DESCRIPTION OF THE PREFERRED EMBODIMENT(S)

Reference is now made to the above-disclosed figures to illustrate exemplary embodiments of the present invention. The exemplary embodiments are disclosed in greater detail according to this detailed description and to the appended drawings wherein like numerals designate like elements.

The disclosed embodiments of the present invention map bits of received data into a theoretical quantum-based model space that is successively easier to work with than known quantum computers. The disclosed embodiments also may account for redundancy to achieve significant encoding or compression of the data.

The disclosed embodiments pertain to a multistate binary encoding technology that is different than known binary encoding processes. The disclosed multistate binary encoding may enable lossless storage and transmission for many different kinds of media, including high definition media having large amounts of data. Computational simulations may be used that behave according to quantum theory principles even though the simulations or models are running on known computers, systems, networks, and the like.

The computational processes and simulations of the disclosed embodiments may describe interactions on a quantum physics level, such that simulations of nature may be enacted. As disclosed in greater detail below, a quantum system may include a set of mathematical rules, such as Hamiltonian operators, that represent the dynamics and total energy of a system in terms of the motion of all its subcomponents. Further, quantum parallelism describes that a single electron may travel along exponentially many different routes simultaneously. Thus, an electron can be in different states or positions though it looks like an electron to an observer.

The disclosed embodiments also incorporate the feature of the entangled particle. The entangled particle may be known as having quantum states that exhibit correlations between states within superpositions. Thus, quantum information, or encoded data, may exist as a linear superposition of two classical or binary, states at the same time. The data may be known as quantum bits. Quantum bits may be homomorphic as they can transform from one state to another without losing data in the second state. As a new quantum bit is added to the encoded data, the number of potential states may double. The states also may be known as quantum states. Thus, a few quantum bits may represent a large number of possibilities using the probability of the states to be a certain value.

Registers for quantum bits, or qubit registers, may hold the superpositions of the states and, by varying the amplitude of at least two states, an infinite number of different superpositions may be created. An infinite number of superpositions and states, however, may be impractical for using on known computers, systems, networks and the like despite the advantages of quantum computing. Thus, the disclosed embodiments may use the advantage of quantum computing to encode large amounts of data, but with the practical feature of interfacing with existing systems.

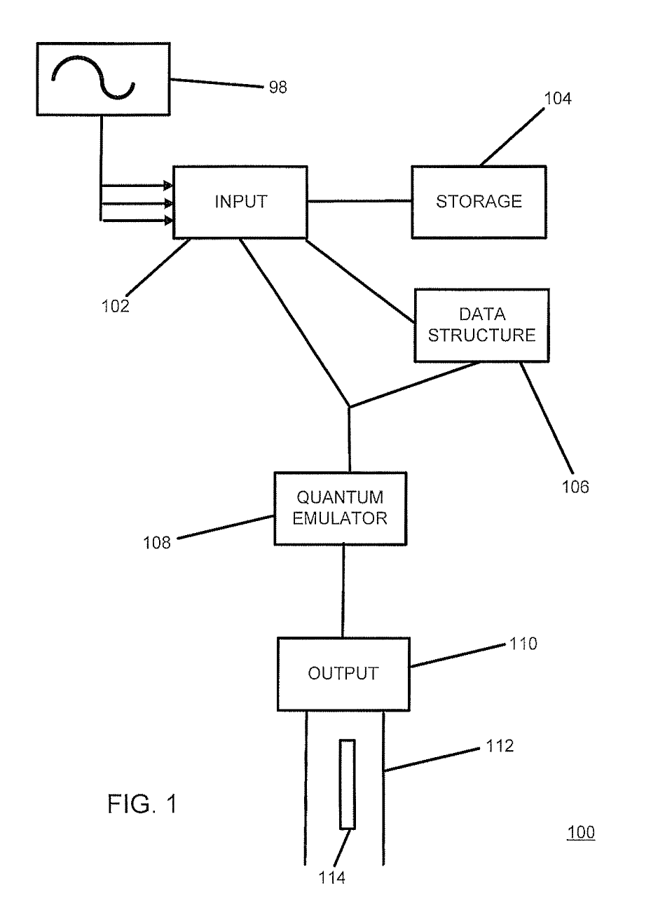

FIG. 1 illustrates a block diagram of quantum encoding system 100 according to the disclosed embodiments. Encoding system 100 also may be known as a compression system, mapping system, data storing system, and the like. Encoding system 100 receives and manipulates data to be output. Encoding system 100 also may be used in an encoder, modem, processor, memory, storage and the like where data is mapped to encoded data to represent the original data in some manner. Preferably, the data is converted to encoded data that is reduced in size compared to the original data.

Encoding system 100 implements computational simulations on known computers, systems, networks, and the like by using probability mathematics to isolate regions within a Hilbert-Banach space to a small, finite set of possibilities. Thus, quantum computers and systems may be exploited by these computational simulations. Therefore, it is not necessary to observe or recreate quanta at the particle structure level as required by known quantum systems.

Instead, the disclosed embodiments use computational simulations that behave as the particle structure level according to quantum theory. For example, an amount of information or data that may be contained on a virtual electron may be at least 32 times greater than previously known. This virtual electron may be known as a quantum representation. The disclosed embodiments, however, also work at the binary level of 0s and 1s. This aspect of the disclosed embodiments may provide a simpler software or hardware implementation of quantum encoding than known compression schemes.

A binary enhancement process facilitates this compatibility to encode or map already compressed information. Already compressed content is not compressible according to known computers, systems, networks, and the like. The disclosed embodiments, however, are not so limited. For example, encoding system 100 may further encode files or data that has been compressed using the JPEG or MPEG formats. Thus, encoding system 100 may be seamless in its implementation as it does not require the removal of existing compression or encoding processes.

Output from encoding system 100, such as encoded data 114, may include encoded quantum bit content that acts like an ordinary bit to binary based systems. When decoded, however, the reconstructed data may be an exact representation of original data 98. For example, no loss of data 98 from its original form may occur by using encoding system 100 in sending encoded data 114 to a destination where it is reconstructed. In another example, encoded data 114 may be stored in a memory by encoding system 100 and retrieved from the memory to be reconstructed. Either example, though, discloses the feature of lossless encoding. Alternatively, loss may occur in the processes if desired by encoding system 100 and the amount of loss may be determined by encoding system 100.

Referring to FIG. 1, encoding system 100 includes input 102. Encoding system 100 also may include storage 104. Storage 104 may be memory, or other type of data storage that is accessible by input 102. Storage 104 also may be a look-up table, a database, and the like. Storage 104 also may be separate from encoding system 100. Storage 104 may store representations of previously encoded data that is matched against data received by input 102. Encoding system 100 also includes data structure 106 that may be retrieved from storage 104. Alternatively, data structure 106 may be generated by input 102. Further, input 102 may be coupled directly to emulator 108 to bypass storage 104. Data structure 106 also may be a code word generated by input 102 in response to data 98.

Encoding system 100 that may create a smaller and more robust waveform. Using base-band encoding and decoding, side-band encoding/decoding, encoding system 100 may use compression and other tools to allocate information to various sub-bands and frequencies. The implementation may be transparent to all media. Further, encoding system 100 may address the last mile question in that it has applicability to existing networks including synchronous optical network carriers.

Referring back to FIG. 1, data 98 is received at input 102. Data 98 may be any type of information that can be represented. Data 98 may be a block of data, or a variable length code of data. A variable length code may be codes of variable, rather than fixed, block length. For simplicity, data 98 may be known as a “block of data” even though data 98 has a variable length and may not be a fixed length.

The application of variable length coding to quantum data compression or encoding via a quantum machine may be discouraging as only a single measurement is available. Additional problems may include uncertainty, calibration, and entanglement. Thus, the disclosed embodiments utilize a controlled environment to bypass these potential problems and to implement variable length coding in a quantum system. These features are disclosed in greater detail below.

For example, quantum emulator 108 emulates the specific goals and synthetic values desired for various generated quantum state information. This feature allows for encoding or compression to be a unitary operation such that it is not necessary for a length measurement to be performed of the variable length states. Emulator 108 observes the minimum energy desired to represent or transmit classical, or known, information contained within a quantum state. The average length of a codeword, such as data structure 106, may be related to the number of shells that are occupied in the resulting quantum representation from emulator 108. Thus, the disclosed embodiments may determine the average energy of data 98 or data structure 106; instead of its average length. Any encoding or compression limit on emulator 108 may result from an energy perspective as opposed to length.

The disclosed embodiments also may send encoded data 114 in the following manner. Encoded data 114 may be a message, or signal, of variable length, and may be continuous as it may not be a block of data having a specified length. Encoded data 114 may be sent over transmission medium 112. Transmission medium 112 may be any medium capable of transmitting energy, signals, waves, particles, bits, and the like. Output 110 may be an output port or other interface from emulator 108 to transmission medium 112. Alternatively, output 110 may be included in emulator 108. Transmission medium 112 may couple to a network, data storage, disk drive, additional circuitry, functions, nodes, routers, computers, and the like. The purpose for using encoded data 114 may be variable and is not limited by the following discussion.

Another feature of the disclosed embodiments may be that data 98 may enter input 102 and go directly to emulator 108 without have to be cached or stored in a memory. Storage 104 is provided in encoding system 100 for storing data or information, or for storing constructs already generated for previous data. Encoding system 100, however, may implement a memoryless source configuration such that data 98 is encoded and transmitted directly.

For example, encoding system 100 may want to send data or a message over transmission medium 112 to a destination to be decoded. Encoding system 100 also may want to send the data in an efficient manner without long delay for large amounts of data. Efficiency may be referred to as the optimization of any one of a number of parameters, such as minimizing the number of bits or the total energy needed to represent the data. These two values are not necessarily the same. Encoding system 100 may communicate a number, or n, of quantum systems prepared from a set of N distinct states. These states, however, may not necessarily be mutually orthogonal.

According to the disclosed embodiments, various properties of quantum systems may be used in encoding data for transmission by encoding system 100. For example, encoding system 100 and emulator 108 may utilize the magnetic spin of the +½ and −½ particles, as denoted by being up or down, as well the frequency, or f. Another utilized degree of freedom, or property, may be the spatial location of coordinates of the particles. With a set of frequencies and the spins, emulator 108 may represent data or information based on quantum properties, including a variable number of photons, by the following basis states: n1, n2, n3, . . . nN; m1, m2, m3, . . . mNi=(n1, up/down), (m1, up/down), and so on.

Thus, N different modes may exist, or modes for N different frequencies, or w may exist, that may be shown as iwN. Each mode may include two different harmonic oscillators, one for each spin. Thus, there may be n1 electrons with frequency w1 in a +½ spin, m1 electrons with frequency w1 in a −½ spin, and so on until nN electrons with frequency wN in a +½ spin and mN electrons with frequency wN in a −½ spin are shown. States with a different number of electrons may be orthogonal. The most general state of this representation is a superposition of all the basis states above.

Many shells for the electrons may exist, but the disclosed embodiments may consider the ones that are occupied. The unoccupied shells may be known as being in a vacuum state. For example, one state, or representation, may include one −½ spin electron in the first shell. All of the states may be generated from the overall vacuum state or zero state, where all the shells are unoccupied. The states may be generated or destroyed by applying creation and annihilation operators, a and a′, respectively, where there are separate operators for both +½ and −½ spin electrons to occupy the shells. Referring to the above example, there is one electron in all the shells between the lowest frequency shell and the first vacuum shell. Representing data or information by the occupation of the shells may involve moving electrons to those shells to create the qubit. Thus, changing from the number of bits in data 98 or n qubits to m qubits may reduce the average energy in transmitting the data or message. This reduction may occur because in order to create or annihilate one electron in the shell wi, emulator 108 should add or release an amount of energy.

A quantum source, preferably within or coupled to emulator 108, may randomly prepare different qubit states with corresponding probabilities, or pi. A random sequence of n states may be produced so that a total density matrix is about equal to Xₚᵢ[fiih˜i].

After encoding by emulator 108, the resulting encoded data 114 may include a smaller number m of qubits, in the state f(m). The ratio of bits of data 98 or n qubits to the resulting m qubits that is minimized by the disclosed embodiments. The density matrix may be in a diagonal form such that the matrix can be diagonalized into eigenvectors and eigenvalues. If a message, or data, of length N is described by the density matrix f(n), then it also may be written in a diagonal basis.

Thus, according to the disclosed embodiments, emulator 108 within encoding system 100 may generate electrons in one of two states. For example, each generated electron may correspond to a letter of a message in data 98. Alternatively, each generated electron may correspond to a bit of data of data 98. The whole length of the message or data is measured by emulator 108. The overlap between the two states may be represented by a consine of the frequency of the states. An encoding rate, or R, may exist that includes two quantum operations C0 and D0 that are analogous to the maps defined for known compression-decompression processes.

Emulator 108 may encode the bits into qubits as disclosed above. The qubits may be represented by encoded data 114. Emulator 108 also may entangle and perform other operations to generate encoded data 114.

Each qubit within encoded data 114 may correspond directly with a shell containing an electron. On average, the disclosed embodiments may reduce n−m electrons for the transmission operation. Assuming all electrons have the same energy of h, wherein all the shells have the same frequency and the energy is the same for both +½ and −½ spins, then the following relationship may be said to exist: initial energy is about equal to h˜nh final energy, or h˜m. With regard to the assumption that all electrons are of the same energy, emulator 108 may determine this in the algorithm as a preset limit for frequencies. The disclosed embodiments also may emit an electron from the same shell, so that the spatial component, or temporal component, of all thes(e) would be different so that the disclosed embodiments may discriminate between the electrons.

In particular, at least one bit of entropy, or heat, in the environment of the message may be generated to delete 1 bit of information from the message when reducing the number of qubits in encoded data 114. For example, if the qubit to be deleted is in the maximally mixed state, then no unitary, or reversible, transformation may exist to map the qubit into a pure state. Thus, the disclosed embodiments may swap a pure qubit from the environment with the maximally mixed one to be deleted. The entropy of the qubit that existed in the message, or received data 98, is transferred to the environment because the whole transformation is, at best, unitary, or reversible, and the environment may not increase in entropy by less than 1 qubit. If the qubit to be erased is originally entangled by emulator 108 to another qubit of the message, then, after the swap operation with the environment, the corresponding environmental qubit becomes entangled with the message, or encoded data 114. Thus, the disclosed embodiments may release energy but not lose any information so as to effect lossless compression. By controlling the release of redundant energy that carries no information, emulator 108 and encoding system 100 may keep the quantum coherences intact.

If n qubits in a state are compressed to m qubits in another state, then efficient compression or encoding may result in nS=mS. In order to minimize the ratio of mm to achieve efficient compression, the entropy of the encoded bit in encoded data 114 should be maximal implying that the frequency has to be in a maximally mixed state.

Encoding system 100 may use emulator 108 to receive data 98 and encode it to encoded data 114. Encoded data 114 may act as known binary bits to the outside world despite being subject to quantum encoding. For example, encoded data 114 may act as 3 bits of binary data generated by encoding system 100. Encoding system 100 encodes each of the bits into either state 0=cos(f/2)[0i]+sin(f/2)[1i] or 1=sin(f/2)[0i]+cos(f/2)[1i] with probability of 0, or p0, equal to the probability of 1, or p1. Preferably, p0=p1=½. In this example, the overlap between the two states is h˜0[1i]=sin f, and they are orthogonal. The states may appear to be of different lengths, but this should not be the case because the missing shells are occupied by vacuum states that carry no information. The state with the highest probability is encoded in the shortest possible form. A high probability may correlate to the state that appears most in a known language or construct. The typical subspace may not have exclusive importance with all the messages or data being encoded faithfully, and the whole transformation is unitary.

This process may be applied to data strings or information of any dimension by continuing with the principle of encoding less probably strings into states with more electrons. To decode, or replace the redundancy that was removed, the disclosed embodiments use the total length of the message in data 98 that was initially encoded, such as the total number of qubits transmitted, instead of the individual lengths of each codeword, or the length of each letter state. By having this total length information, the disclosed embodiments know the redundancy needed to add to the compressed signal, or encoded data 114, which contains the signal having the statistical properties of the original message, or data 98. Thus, the original data 98 may be restored by adding the redundancy. This value should be known by encoding system 100 and sent in additional to encoded data 114, or, alternatively, placed into encoded data 114.

Thus, when n units of information or data are erased, the entropy of the environment is increased by n units. These units may be bits of data or already generated qubits. Further, encoding system 100 may send this information along with the encoded data, either as part of encoded data 114 or as a separate piece of information. This information may be the total length of the uncompressed or unencoded message, or, alternatively, the entropy of the message, or encoded data 114. If the statistical properties of encoded data 114, or message, is referred to as fn, then the disclosed embodiments may send additional log n qubits in encoded data 114 with the encoded message to represent the length of the total signal, or data 98, keeping in mind that data 98 may be of a variable length. The average word length may be defined as the corresponding 1 to 1 entropy.

The disclosed embodiments shown by FIG. 1 may provide the following features in transitioning from binary to quantum states, and vice versa. For example, a 2, 4, 8, 16, 32, . . . 1024 or above binary representation may be transported in an electron structure. Entanglement parallelism may be allowed along with signal summation. Variable length codes may be utilized to achieve higher rates of effective compression or encoding using encoding system 100. Mappings from binary states to electron states is reversible to maintain fidelity of the data. The electrons structures may be known as codewords for the encoding system of the disclosed embodiments. All quantum channels and quantum exercises may be performed in an emulated environment, such as in an encoder or decoder. Thus, transmitted data and received data over known or classical systems may be in binary form so as to be transparent to existing systems and not disruptive. New hardware or transmission medium may not be needed to implement the disclosed embodiments.

Further, additional prefixing on electrons, as discussed above, may be in an observable state to yield higher compression. Electron information for use as an observable may be a predetermined and fixed value in the implementation of selected mathematical formula. According to the disclosed embodiments, a standard quantum electron structure may map incoming strings using the four prime quantum numbers: principal, angular movement or azimuthal, magnetic and spin. In using the four prime quantum numbers as a cavity for binary information, the disclosed embodiments may utilize the magnetic value and shells as a container and use the principal, angular and spin symbols to reduce the size of the library codewords. A specific energy level, or another static observable, may be assigned to each produced electron and mapped against the binary information it holds.

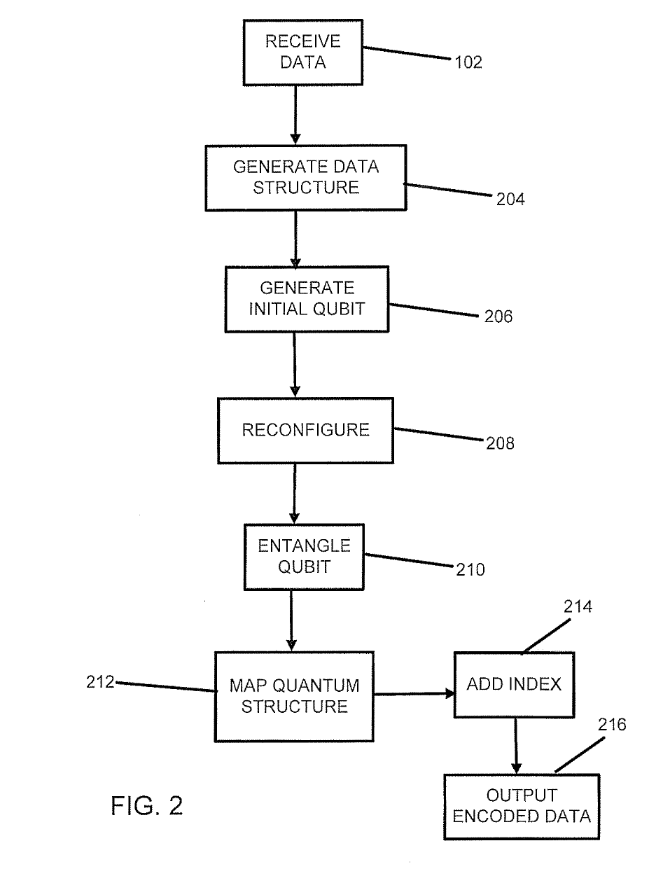

FIG. 2 depicts a flowchart for processing data using a quantum system according to the disclosed embodiments. FIG. 2 may referenced features disclosed by FIG. 1, but is not limited to encoding system 100 discussed above. Further, FIG. 1 is not limited by features disclosed by FIG. 2. FIG. 2 also may be implemented in a variety of devices that transmit, store, convert, encode, compress or process data or information.

Step 202 executes by receiving data to be encoded. Referring to FIG. 1, data 98 is received by input 102. The data may be fixed or variable length data. Further, the received data may be in any format, including a compression format, such as MPEG or JPEG. The received data also may be multiplexed data received over a network from a plurality of inputs and to be encoded by an encoder, such as encoding system 100. Step 204 executes by generating a data structure for the received data. The data structure may be a construct stored elsewhere and retrievable by the encoder. Alternatively, the data structure may be a model of a quantum presentation, system or structure that is created to encode the data. The data structure may be a theoretical physical model space. Because the received data may be fixed or variable, the data structure is not limited to a certain size and also may be variable, The disclosed embodiments also may skip step 204 and not generate a data structure for the received data.

Step 206 executes by generating an initial qubit from the data structure or received data. As disclosed above, the shells of the qubit may be filled by electrons in a variety of configurations, preferably corresponding to the quantum numbers for the electrons. The electrons may represent the received data. The probability of the states or configuration for the electrons may be 1 to insure integrity of the values of the encoded data. For example, the disclosed embodiments may set the probability of an electron in a shell within the qubit having a spin of +½ as being about 1. The probability even may be greater than 0.50 to meet this parameter. In any event, the disclosed embodiments should have confidence that the quantum numbers, or values, specified for the electrons are indeed those numbers.

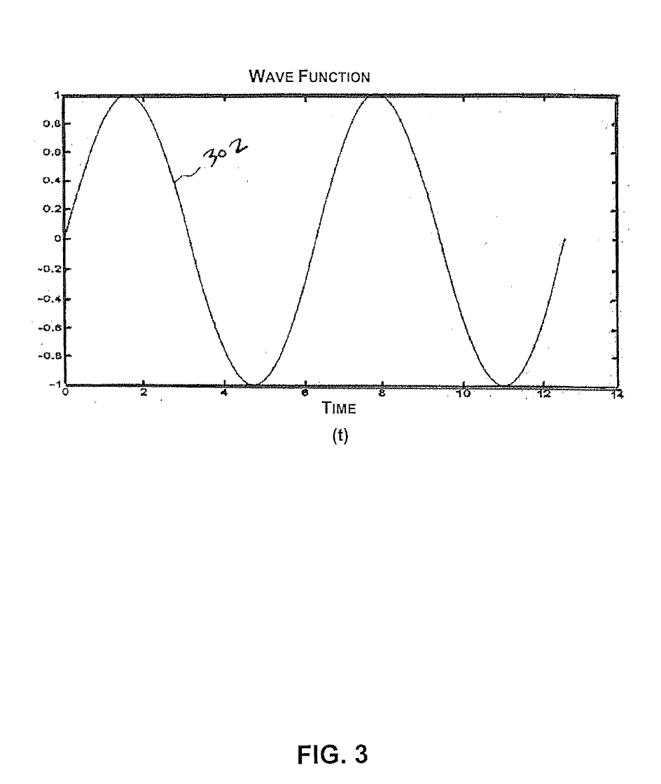

Step 208 executes by reconfiguring the states or electrons within the qubit and any other applicable qubit. In order to address redundancy issues, electrons may be moved to lower or higher shells. Step 210 executes by entangling the qubit with another qubit so as to evolve the resulting quantum system or representation. Evolving the quantum system into an entangled state includes using operators that are reversible and having a complementary form. For example, a Hamiltonian operator may be used. A Hamiltonian operator may generate the time evolution of a system that allows the disclosed embodiments to observe the system at a given point in time. The resulting quantum system, or representation, may be viewed as a wave, and described using the Schrödinger wave equation, normalized and simplified, or i (∂/∂t) Ψ=ĤΨ. When depicted over time, the quantum system may resemble a wave function as shown in FIG. 3.

Referring to FIG. 3, wave 302 may start at t=0. The disclosed embodiments may search for points along wave 302 that have one of the states of the combined qubit functions has the probability of, or close to, 1. The other state of the function may be equal, or close to, 0. Thus, the disclosed embodiments may search wave 302 to determine a point where all of the coefficients, except one, is equal or approximately equal to zero. An elegant operator also may used to evolve the quantum system as this search occurs. For example, the disclosed embodiments may search wave 302 for the point where all the coefficients, except the third one, for a 2 qubit encoded data are approximately equal to 0, or Ψ=0[00]+0[01]+1[10]+0[11]. According to the example, there is a high probability or certainty that the 2 qubits are the third state, or the first qubit is 1 and the second is 0, from a binary perspective.

Using the identified point from the above example, a mathematical model may be developed that becomes the basis for the algorithm used step 212 to map the quantum structure of the encoded data to the bits. The outcome of the mapping may be that only one state is shown, or [10]. Thus, step 214 executes by adding an index to the qubits to identify the desired quantum state, or [10]. For 2 qubits, such as the example above, the index may be 2 bits when [10] is the quantum state. For 4 qubits, the index may be 4 bits, and so on.

Step 216 executes by outputting the encoded data. As disclosed above, the encoded data may be transmitted, stored, converted, downloaded, multiplexed, and the like. The encoded data includes the index and the number of steps or time desired to step in order to find the point identified above at which all but one of the coefficients are approximately equal to 0. Referring to the above example, if 68 “steps” are included between to and the identified point on wave 302, then a total of 9 bits may be outputted during step 216. These 9 bits may be broken down as 2 for the quantum state of [10] and 7 to represent the number 68 to a known binary system. With 2 qubits having 48 bits each, a compression ratio of 10:1 may be achieved.

To decode the outputted encoded data, a decoder may know the number of qubits and the operator, or index, used. The combined wave function disclosed above may be known on the decoder side. The decoder may fill the coefficients of the quantum states with 0, except for the one coefficient desired to be 1. The one state that was transmitted is set to a coefficient of 1. The decoder may use the submitted number of steps to step “back in time” the appropriate number of time. According to the example, the number of steps may be 68. The resulting quantum system, or representation, would be the one encoded, as disclosed above. The coefficients are extracted and used to reconstruct the properties of the original qubits. The qubits may provide a 1 to 1 mapping to reproduce the original bitstream received.

Thus, the disclosed embodiments provide the features of using a binary enhancement algorithm to make information accessible from a physical media, such as known and classical computers, systems, networks, and storage. A probability assignment incorporates what is known about a set of alternatives. The disclosed embodiments may solve the problem of storing and retrieving information from physical media by being able to pick one alternative out of a set of possible alternatives that are called “states” or “microstates,” as disclosed above, and applicable to both quantum and binary systems. A classical system may be located at a point in phase space, and its dynamics trace out a path through phase space. The dynamics of quantum systems may unfold within the boundaries of a projective Hilbert space and trace out a path in the projective Hilbert space.

The disclosed embodiments may add some dimensional complexities to keep the information finite in the quantum systems. The disclosed embodiments use simulations and complex number classes that are used to define a vector in Hilbert/Banach space because of the complexities. The probability of measuring the various states having a complex amplitude that correlates to a respective complex number may be calculated by a mathematical algorithm. The disclosed embodiments may define rules and member functions to actuate the qubits into a non-quantum computing environment.

The disclosed embodiments may use a single affine transform that represents the embodied information. The disclosed embodiments may apply rules into an agent algorithm that designates the four quantum numbers, or n, l, m and s, as described in Schrödinger's wave equation and their behaviors to a mapped model. The disclosed embodiments may generate a single affine transform that represents the encoded information stored in an electron in a pseudo-electron environment. A four-dimensional lattice/array may be utilized to collect the information. Compiled binary mapping may be run through a synthetic quantum algorithm and the ordinary bits of binary or analog information are transposed into an electron-like setting.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

What is claimed is:

1. A method for processing data, the method comprising:
generating a qubit to represent data;
entangling said qubit with another qubit by reconfiguring a quantum structure within said qubit or said another qubit; and
mapping said quantum structure into encoded data, wherein said encoded data is useable for a non-quantum environment.

2. The method of claim 1, further comprising using an energy level to represent said data in said qubit.

3. The method of claim 2, further comprising moving an electron according to said energy level to a shell, wherein said shell corresponds to a bit of said data.

4. The method of claim 1, further comprising determining a probability for a state representing said qubit and said another qubit.

5. The method of claim 4, wherein said determining comprises determining a point on a waveform for said qubit and said another qubit, said point indicating said probability.

6. The method of claim 5, further comprising adding an index to said encoded data corresponding to said point on said waveform.

7. The method of claim 1, further comprising creating a data structure from said data.

8. The method of claim 1, further comprising retrieving a data structure according to said data.

9. The method of claim 1, further comprising transmitting said encoded data.

10. The method of claim 1, further comprising storing said encoded data.

11. The method of claim 1, further comprising achieving a ratio of a size of said data to a size of said encoded data of at least about 10 to 1.

12. The method of claim 1, wherein said data comprises variable length data.

13. A method for encoding data, the method comprising:
creating a quantum structure for properties of an electron;
encoding the quantum structure into a qubit;
entangling the qubit into encoded data; and
adding an index to said encoded data, wherein said index corresponds to a probability of a state for said qubit.

14. The method of claim 13, further comprising determining said probability of said state.

15. The method of claim 13, further comprising determining quantum numbers for said electron.

16. An encoding system, comprising:
an emulator to generate a qubit having a quantum structure having properties for an electron;
another qubit to entangle with said qubit to generate encoded data representing data; and
an input to receive said data,
wherein a probability is determined for a state of said qubit and said another qubit, and an index is added to said encoded data correlating to said probability.

17. A system for processing data, the system comprising:
generating means for generating a qubit to represent data;
entangling means for entangling said qubit with another qubit by reconfiguring a quantum structure within said qubit or said another qubit; and
mapping means for mapping said quantum structure into encoded data, wherein said encoded data is useable for a non-quantum environment.

18. A computer program embodied on a computer-readable medium to control a processor to process data, the computer program performing the steps of:
generating a qubit to represent data;
entangling said qubit with another qubit by reconfiguring a quantum structure within said qubit or said another qubit; and
mapping said quantum structure into encoded data, wherein said encoded data is useable for a non-quantum environment.
